(19) United States
(12) Patent Application Publication
(10) Pub. No.: US 2005/0064629 A1
(43) Pub. Date: Mar. 24, 2005

(54) Tungsten-copper interconnect and method for fabricating the same

(76) Inventors: Chen-Hua Yu, Keelung City (TW); Tsu Shih, Changhua County (TW); Chung-Shi Liu, Hsinchu City (TW); Shwang-Min Jeng, Hsinchu (TW); Horng-Huei Tseng, Hsinchu (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/665,309

(22) Filed: Sep. 22, 2003

(51) Int. Cl. H01L 21/44

(52) U.S. Cl. 438/118

(57) ABSTRACT

An interconnect structure utilizing a silicon carbon-containing film as an interlayer between dielectrics. A semiconductor substrate having a conductor thereon is provided, and an insulating layer overlies the semiconductor substrate. The insulating layer has a via hole therein to expose the conductor. A conductive plug, e.g. a tungsten plug, substantially fills the via hole and electrically connects the underlying conductor. A silicon carbon-containing film and a low k dielectric layer overlie the insulating layer and the conductive plug, and have a trench therein exposing the conductive plug. A copper or copper alloy conductor substantially fills the trench.

### BACKGROUND OF THE INVENTION

1. Field of the Invention

The present invention relates to semiconductor fabrication, and in particular to tungsten-copper interconnect structure, and method for fabricating the same.

2. Description of the Related Art

Metallization in wafer fabrication is a process of depositing metal film over a dielectric film, wherein the metal film is defined to form the interconnecting metal lines and plugs of integrated circuits. As density of circuit elements increases, interconnect resistance and parasitic capacitance do as well, thereby slowing signal propagation. Currently, copper interconnects are formed using a so-called “damascene” or “dual-damascene” fabrication process rather than conventional aluminum interconnects, thereby reducing interconnect metal resisitivity. Briefly, a damascene metallization process forms conductive interconnects by deposition of conductive metals, i.e. copper or copper alloy, in via holes or trenches formed in a semiconductor wafer surface.

Multilevel metallization creates the need for billions of vias filled with metal plugs to form electrical pathways between two metal layers. Contact plugs are also used to connect the silicon devices in the wafer to the first level of metallization. The most common metal used for contact plugs is tungsten (W). Tungsten has been used as a plug material because of its ability to uniformly fill high-aspect ratio vias when deposited by chemical vapor deposition (CVD). Tungsten is resistant to electromigration failure. It also serves as a barrier to diffusion and reaction between silicon and the first metal layer.

FIG. 1 shows a conventional contact structure. A MOS device is disposed on a silicon substrate 100, comprising a gate structure 110, source/drain regions 112, and silicide layers 113 and 115 directly overlying source/drain regions 112 and 114. A thick oxide layer 120 covers the MOS device and local tungsten plugs 124 are disposed in the oxide layer 120 to contact silicide layers 113 and 115 on the source/drain regions 112 and 114, where a glue layer 122 is interposed between the tungsten plugs 124 and the oxide layer 120. Another oxide layer 130 is deposited over the oxide layer 120 and via plug interconnects 134 are disposed in the oxide layer 130 to contact the local tungsten plugs 124. Similarly, a glue layer 132 is interposed between the tungsten plugs 134 and the oxide layer 130. Conventionally, an etch-stop layer 136 is deposited over the oxide layer 130 and tungsten plugs 134. An inter-layer dielectric (ILD) layer 140 is subsequently deposited over the etch-stop layer 136, wherein metal lines 144, serving as metal 1, are disposed to contact the tungsten via plugs 134. The metal lines 144 are isolated from the oxide layer 130 and the dielectric layer 140 by diffusion barrier 142. Conventionally, the metal lines 144 are formed by copper damascene process. Ti/TiN is conventionally utilized as glue layers 122 and 132 and Ta/TaN is conventionally utilized as diffusion barrier layer 142.

Lin, U.S. Pat. No. 6,140,224, discloses a method for forming tungsten plugs, in which a polishing stop layer is introduced as a CMP stop layer to prevent dishing.

The drawback of the conventional tungsten-copper interconnects is high RC delay with the high-K etch-stop layer, e.g. SiN, thereby slowing signal propagation.

### SUMMARY OF THE INVENTION

The object of the invention is to provide a tungsten-copper interconnect structure with reduced RC delay, and a method for fabricating the same.

To achieve the object, an interconnect structure utilizing a silicon carbon-containing film as an inter-dielectric layer is provided. A semiconductor substrate having a conductor, such as nickel silicide, thereon is provided, with an insulating layer overlying the semiconductor substrate. The insulating layer has a hole therein. A conductive plug, e.g. a tungsten plug, substantially fills the via hole and electrically connects the underlying conductor. A silicon carbon-containing film and a low dielectric constant layer overlie the insulating layer and the tungsten plug, and have a trench therein. A copper or copper alloy conductor substantially fills the trench, which electrically connects the underlying conductive plug.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-section of a conventional contact interconnect structure; and

FIGS. 2 to 6 are cross-sections showing the process of fabricating a tungsten-copper interconnect structure of the invention.

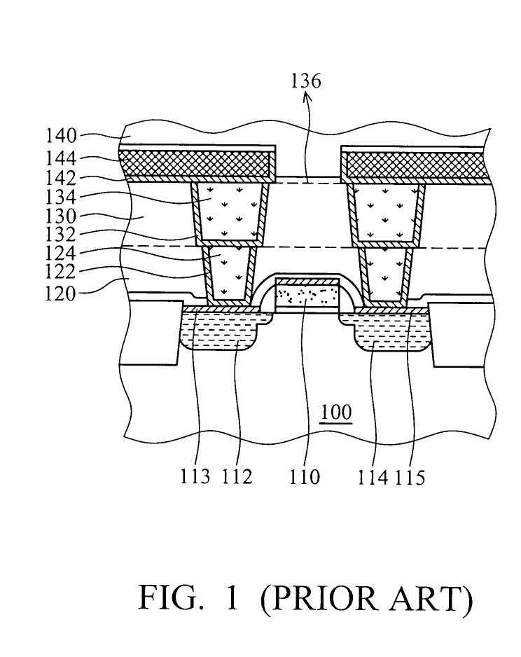

### DETAILED DESCRIPTION OF THE INVENTION

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers.

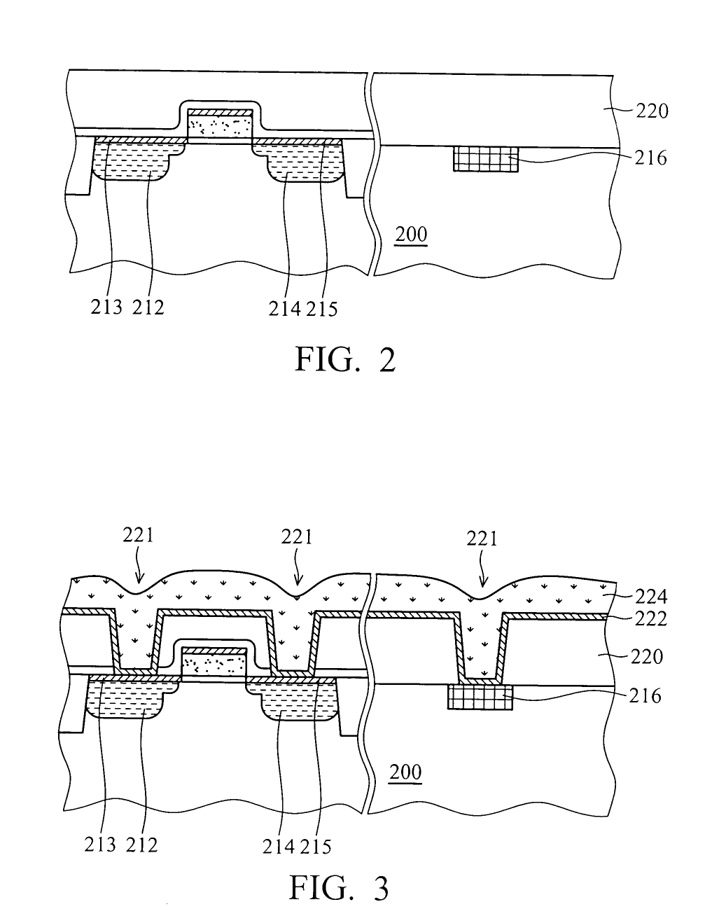

FIGS. 2 to 6 are cross-sections showing the process of fabricating a tungsten-copper interconnect structure of the invention.

As shown in FIG. 2, a MOS structure is formed on a semiconductor substrate 200, e.g. a silicon substrate or a silicon germanium substrate, having metal silicide layers 213 and 215 directly on source/drain regions 212 and 214. A conductor 216 is also disposed on another region of the semiconductor substrate 200. The preferred conductor 216 is composed of doped semiconductor, polysilicon, metal silicide, metal, metal alloy, metal compound or a combination thereof and the preferred metal silicide is nickel silicide. An insulating layer 220 is deposited on the surface of the semiconductor substrate 200. The preferred insulating layer 220 is undoped silicate glass (USG) formed by atmospheric pressure CVD (APCVD) or low pressure CVD (LPCVD).

The insulating layer 220 is then etched by way of conventional photolithography to form contact via holes 221 therein, exposing the underlying metal silicide layers 213 and 215 and the conductor 216. The preferred width of via holes 221 is less than 950A. A glue layer 222 can be optionally deposited conformally on the surface of the insulating layer 220 and the contact via holes 221 as a lining layer to improve adhesion between the insulating layer 220 and the subsequent tungsten plugs. The preferred glue layer 222 is TiN or Ti, which may also serve as a diffusion barrier layer to block tungsten out-diffusion to the insulating layer 220. Tungsten 224, the preferred conductive material as a via plug, is then deposited on the surface of the glue layer 222 to fill the contact opening 221 substantially, by way of CVD, as shown in FIG. 3. CVD provides a superior filling capability of high-aspect ratio vias, such as vias with a width less than 950 Å. Planarization, e.g. chemical mechanical polishing (CMP), is performed to remove excess tungsten and glue layer 222 from the surface of the insulating layer 220, thereby forming tungsten contact plugs 224 connecting the underlying metal silicide layers 213 and 215 and conductor 216.

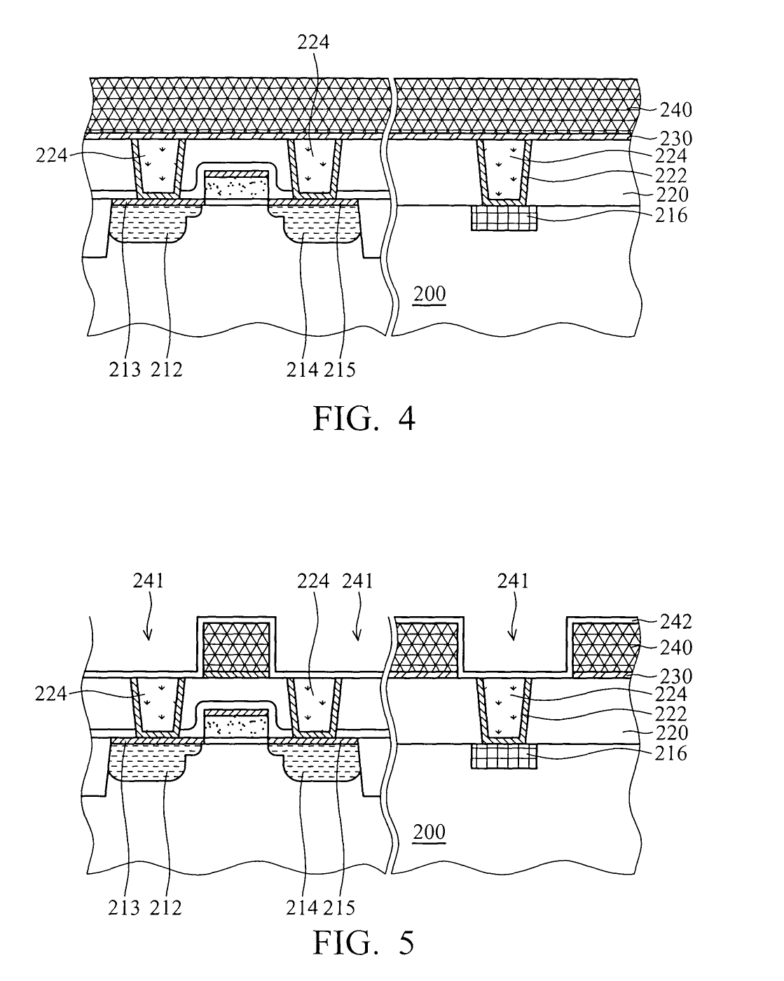

In FIG. 4, a silicon carbon-containing film 230 is deposited over the surface of the insulating layer 220 and tungsten via plugs 224. The preferred silicon carbon-containing film 230 is a silicon carbide film with carbon content exceeding 20%, such as SiC, SiCO or SiCON, and a thickness less than 500 Å. The silicon carbide film can be deposited by plasma enhanced CVD (PECVD) with Si(CH₃)₄ or SiH(CH₃)₃ as source material. The silicon carbon-containing film 230 serves as an etch stop layer for the subsequent trench recess and an adhesion layer between the insulating layer 220, i.e. USG, and the subsequent low-k dielectric layer. The dielectric constant (k) of silicon carbide (k=4-5) is lower than conventional etch-stop material, e.g. silicon nitride (k=7-8), thereby reducing the dielectric constant of the inter-layer dielectrics in interconnects.

As shown in FIG. 4, a dielectric layer 240 is subsequently deposited on the surface of the silicon carbon-containing film 230. The preferred dielectric layer is dielectric material with a dielectric constant (k) less than 3.0, such as organosilicate glass (OSGs), i.e. Black Diamond(trade), obtained from Applied Materials Corporation of Santa Clara Calif., which has dielectric constants as low as 2.6-2.8. Low-k dielectric materials such as SOGs (spin-on-glass) can be formed from alcohol soluble siloxanes or silicates spin-deposited and baked to form a relatively porous silicon oxide structure. Inorganic low k material can be utilized as the dielectric layer 240 as well. In an embodiment, low-k dielectric layer 240 can be formed by chemical vapor deposition (CVD) and/or Spin-On method.

In FIG. 5, the low-k dielectric layer 240 is then etched by way of conventional photolithography to etch the dielectric layer 240 and form trenches 241 therein with the silicon carbon-containing film 230 as an etch-stop layer. The depth of the trenches 241 can be controlled thereby. The silicon carbon-containing film 230 on the bottom of the trenches 241 can be further removed by adjusting etching recipe to expose the underlying tungsten contact plugs 224. The preferred width of trenches 241 is less than 1300 Å. Preferably, a diffusion barrier layer 242 is subsequently deposited conformally on the surface of the low-k dielectric layer 240 and the trenches 241. The diffusion barrier layer 242 can be tantalum (Ta) or tantalum nitride (TaN) formed by high-density plasma CVD (HPCVD) or ionized metal plasma PVD for blocking copper out-diffusion.

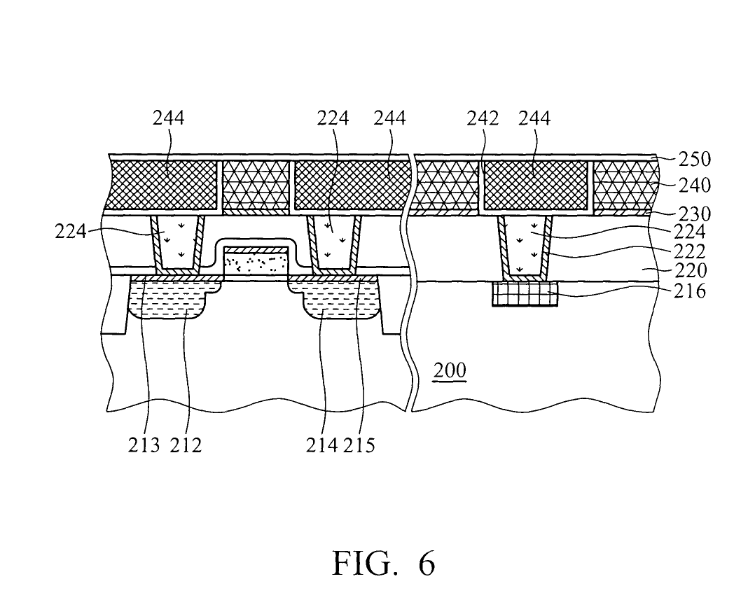

In FIG. 6, copper or copper alloy is deposited on the surface of the diffusion barrier layer 242, substantially filling the trenches 241. Preferably, the copper or copper alloy is deposited by chemical vapor deposition (CVD), physical vapor deposition (PVD) and/or plating. In an embodiment, a thin copper or copper alloy layer (not shown) can be deposited on the diffusion barrier layer 242 as a seed layer of copper deposition, lining the trenches 241 by way of conventional PVD, CVD or ALCVD, or wet plating.

The excess copper or copper alloy is then removed by chemical mechanical planarization (CMP), which planarizes the surface in preparation for the next level. The resulting copper or copper alloy metal lines 244 connect the tungsten via plugs to form the circuitry. An etch-stop layer 250, preferably a silicon carbon-containing layer, is deposited on the surface of the copper or copper alloy metal lines 24 and the low-k dielectric layer 240 for subsequent process. Similarly, the silicon carbon-containing can serve as an etch stop layer for the subsequent via hole recess, an adhesion layer between the dielectric layer 240 and the subsequent dielectric layer, and a diffusion barrier layer for capping the copper or copper alloy conductor 244.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for fabricating a metal structure, comprising:
providing a semiconductor substrate with a conductor thereon;
forming an insulating layer overlying the semiconductor substrate;
forming a hole in the insulating layer exposing the conductor;
substantially filling the hole with a conductive material as a conductive plug;
forming a silicon carbon-containing film;
forming a low dielectric constant layer;
forming a trench in the low dielectric constant layer and the silicon carbon-containing film;
forming a lining layer on the trench; and
substantially filling the trench with copper or copper alloy electrically connecting the conductive plug.

2. The method as claimed in claim 1, wherein the conductive material comprises tungsten.

3. The method as claimed in claim 1, wherein the conductor comprises metal silicide.

4. The method as claimed in claim 1, wherein the semiconductor substrate comprises silicon.

5. The method as claimed in claim 1, wherein the semiconductor substrate comprises silicon germanium.

6. The method as claimed in claim 1, wherein the conductor is composed of doped semiconductor, polysilicon, metal, metal compound or a combination thereof.

7. The method as claimed in claim 1, wherein the insulating layer comprises undoped silicate glass (USG).

8. The method as claimed in claim 1, wherein the thickness of the silicon carbon-containing film is less than 500 Å.

9. The method as claimed in claim 1, wherein the silicon carbon-containing film is silicon carbide(SiC).

10. The method as claimed in claim 1, wherein the carbon content of the silicon carbon-containing film exceeds 20%.

11. The method as claimed in claim 1, wherein the dielectric constant (k) of the low dielectric constant layer is less than 3.0.

12. The method as claimed in claim 1, wherein the low dielectric constant layer is formed by chemical vapor deposition (CVD) and/or Spin-On method.

13. The method as claimed in claim 1, wherein the low dielectric constant layer comprises inorganic film and/or organic film.

14. The method as claimed in claim 1, wherein the width of the hole is less than 950 Å.

15. The method as claimed in claim 1, wherein the width of the trench is less than 1300 Å.

16. The method as claimed in claim 1, wherein the lining layer comprises Ta and/or TaN.

17. The method as claimed in claim 1, wherein the copper or copper alloy is formed by chemical vapor deposition (CVD) and/or physical vapor deposition (PVD).

18. The method as claimed in claim 1, wherein the copper or copper alloy is formed by plating.

19. A metal structure, comprising:
a semiconductor substrate with a conductor thereon;
an insulating layer overlying the semiconductor substrate having a hole therein exposing the conductor;
a conductive plug substantially filling the hole and electrically connecting the underlying conductor;
a silicon carbon-containing film overlying the insulating layer and the conductive plug;
a low dielectric constant layer overlying the silicon carbon-containing film;
a trench in the low dielectric constant layer and the silicon carbon-containing film; and
a copper or copper alloy conductor substantially filling the trench, electrically connecting the conductive plug.

20. The structure as claimed in claim 19, wherein the conductive plug comprises tungsten.

21. The structure as claimed in claim 19, wherein the conductor comprises metal silicide.

22. The structure as claimed in claim 19, wherein the semiconductor substrate comprises silicon germanium.

23. The structure as claimed in claim 19, wherein the conductor is composed of doped semiconductor, polysilicon, metal, metal compound or a combination thereof.

24. The structure as claimed in claim 19, wherein the insulating layer comprises undoped silicate glass (USG).

25. The structure as claimed in claim 19, wherein the thickness of the silicon carbon-containing film is less than 500 Å.

26. The structure as claimed in claim 19, wherein the silicon carbon-containing film comprises silicon carbide (SiC).

27. The structure as claimed in claim 19, wherein the carbon content of the silicon carbon-containing film exceeds 20%.

28. The structure as claimed in claim 19, wherein the dielectric constant (k) of the low dielectric constant layer is less than 3.0.

29. The structure as claimed in claim 19, wherein the low dielectric constant layer is formed by chemical vapor deposition (CVD) and/or Spin-On method.

30. The structure as claimed in claim 19, wherein the low dielectric constant layer comprises inorganic film and/or organic film.

31. The structure as claimed in claim 19, wherein the width of the hole is less than 950 Å.

32. The structure as claimed in claim 19, wherein the width of the trench is less than 1300 Å.

33. The structure as claimed in claim 19, wherein the lining layer comprises Ta and/or TaN.

34. A metal structure, comprising:
a semiconductor substrate with a nickel silicide thereon;
an insulating layer overlying the semiconductor substrate having a hole therein exposing the conductor;
a conductive plug substantially filling the hole and electrically connecting the underlying conductor;
a silicon carbon-containing film overlying the insulating layer and the conductive plug;
a low dielectric constant layer overlying the silicon carbon-containing film;
a trench in the low dielectric constant layer and the silicon carbon-containing film; and
a copper or copper alloy conductor substantially filling the trench, electrically connecting the conductive plug.

35 The structure as claimed in claim 34, wherein the conductive plug comprises tungsten.

36. The structure as claimed in claim 34, wherein the thickness of the silicon carbon-containing film is less than 500 Å.

37. The structure as claimed in claim 34, wherein the carbon content of the silicon carbon-containing film exceeds 20%.

38. The structure as claimed in claim 34, wherein the dielectric constant (k) of the low dielectric constant layer is less than 3.0.

39. The structure as claimed in claim 34, wherein the width of the hole is less than 950 Å.

40. The structure as claimed in claim 34, wherein the width of the trench is less than 1300 Å.

41. The structure as claimed in claim 34, wherein the lining layer comprises Ta and/or TaN.
